(19) United States
(12) Patent Application Publication
(10) Pub. No.: US 2010/0087323 A1
(43) Pub. Date: Apr. 8, 2010

(54) Method of enhancing efficacy of electrical apparatuses

(76) Inventor: Alexander Yabrov, Princeton, NJ (US)

Correspondence Address: Yabrov Alexander, 70 Roper Road, Princeton, NJ, 08540, US

(21) Appl. No.: 12/286,257

(22) Filed: Sep. 30, 2008

(51) Int. Cl. H01L 39/02; H01J 25/00

(52) U.S. Cl. 505/200; 505/150

(57) ABSTRACT

The present invention is a method of enhancing efficacy of electrical apparatuses by using the augmented velocity electrons.

### CROSS-REFERENCE TO RELATED APPLICATIONS

N/A

### REFERENCES CITED

U.S. Patent Documents

| | | |
|---|---|---|
| 4,279,865 | March 1988 | Busch |
| 5,015,920 | May 1991 | Blanchard |

### OTHER REFERENCES

De Broglie L. Physics and Microphysics. Grosset & Dunlap, NY, 1955.
Diner S., at al. The Wave-Particle Dualism. D. Reidel Publishing Co., Boston, 1984.
Heisenberg W. Physics and Philosophy. Harper, N.Y., 1958.
Monoux P., at al. Superconductivity without phonons. Nature, 450(7173):1177-83, 2007.
Wheeler J A. A Journey into Gravity and Spacetime. Scientific American Library, NY, 1990.
Yabrov A. Relativity of Uncertainty. Interaction of the Microworld and Spacetime. World Scientific, Singapore, 2009.

### STATEMENT REGARDING FEDERALLY SPONSORED RESEARCH OR DEVELOPMENT

N/A

### REFERENCE TO SEQUENCE LISTING, A TABLE, OR A COMPUTER PROGRAM LISTING COMPACT DISC APPENDIX

N/A

### BACKGROUND OF THE INVENTION

1. Field of Invention

This invention relates to enhancement of efficacy of the electrical apparatuses using the augmented velocity electrons in particular via superconductivity.

2. Description of the Prior Art

Superconductivity is the state in which a conducting material has no resistance to electrical current. In 1911, Onnes discovered that mercury cooled by liquid helium to 4 degrees Kelvin—looses resistance to electrical current. Later, it was shown that many other metals were also superconductive when cooled to extremely low temperatures.

Theory of the low temperature superconductivity was introduced in 1957 by Bardeen, Cooper, and Schriffer. The BCS theory suggested that cryogenic cooling of materials such as niobium suppressed the random thermal noise in their crystal structure. This allowed quantized mechanical vibrations (“phonons”) to set up a weak electrical interaction that coupled electrons with opposite spin and momentum together in “Cooper pairs”, which had zero net spin and momentum. The binding of electrons in Cooper pairs eliminates scattering, and so electrical resistance disappears.

Starting from 1986, a second kind of the materials was discovered, which were named high temperature superconductors (HTS). These materials—mainly various alloys—demonstrated superconductivity at the temperatures, which—though remaining low—were essentially above those close to zero Kelvin. Since 1986, over 100 HTS materials have been discovered. Now the record Tc is close to 140 degrees Kelvin. This moved the Curie temperatures of superconducting materials from the range of liquid helium temperatures to those of liquid nitrogen temperatures.

Recently, another kind of superconducting materials has attracted especial attention. These are the so-called heavy electron superconductors that superconduct at up to twice the temperature at which nitrogen liquefies. For the convenience of differentiation, I name them here—the “third kind” superconductors. “If we ever find a material that superconducts at room temperature—the ‘Holy Grail’ of superconductivity—it will be within this class of materials,” says Pines (see Montoux at al., 2007).

The BCS theory is not applicable for explanation of the HTS superconductivity. Most researchers consider that the mechanisms suggested by the BCS, in particular the phonons, do not play role in superconductors of the 2^{nd} kind. The same is being said about the heavy electron superconductors. Pines and coauthors name the inner magnetic interactions related to the electron's spins to be the mechanism responsible for the formation of a coherent current of heavy electrons.

In summary, to date, practical application of the phenomenon of superconductivity is considerably restrained by the necessity of maintaining the entire conducting system under the condition of a very low temperature. An efficacious method of superconducting at room temperature is the task of the day.

### BRIEF SUMMARY OF THE INVENTION

Invented is a new method of enhancement of efficacy of electrical supply by using electrons moving with augmented speed sufficient for creation of a coherent, unison current of electrons. The new method opens broad area of possible applications—for electrical cars, trains, airplanes, ships, communication devices, betavoltaic devices, etc.

### BRIEF DESCRIPTION OF THE DRAWINGS

FIG. 1—depicts the spacetime-dent wrapping an electron. According to the method of the invention, an electron has been accelerated so that its increased mass is sufficient to form a spacetime-dent. Grip of the spacetime-dent thwarts the wave function of the electron.

FIG. 2—depicts a device allowing injecting beta electrons into the electrical current. It shows a hollow (vacuum) capacity—(1); having a wire handle—(2) to which a potential difference is applied. Inside this capacity, a radioactive material is placed—as the source of beta electrons (e.g. Stroncium-90). Diameter of the inner space of the sphere (1) is 1 sm. Length of the wire loop (2) is 5 sm; diameter of the wire—0.3 sm. Size of the radioactive sample—0.01 gm.

### DETAILED DESCRIPTION OF THE INVENTION

As shows analysis of the prior art, a complete theory of the high temperature superconductors is still absent. Currently, the attention of the investigators is centered primarily upon the materials which provide for superconductivity—their chemical nature and composition, and their molecular structure. Intensively studied also are the mechanisms (phonons and others) responsible for the phenomenon depending on the properties of said materials under the conditions of low temperature.

Our attention is centered, first of all, on electrons—the carriers of the electrical current. Thorough comparative analyses of voluminous pertinent data led me to a certain generalization. Independently on the kinds of the materials and the possible mechanisms responsible for superconductivity at the very low, as well as at the higher (but still low) temperatures reached today—the common and, on my view, the leading feature of the phenomenon of superconductivity in its entirety is the formation of a coherent current of electrons moving in unison. This is this specific kind of an electron current, which provides for the phenomenon of superconductivity. Low temperature represents a necessary factor for creation of a coherent electron current by the methods applied today. Mechanisms activated by low temperature (phonons, inner magnetic interactions, and others) create a coherent current of electrons whose wave function is acting in unison.

Thus a quantum mechanical phenomenon characteristic for individual electrons is manifested at a macroscopic scope—all carriers in the superconducting current acting as one body. Low temperature also prevents accidental deviations of electrons from the coherent current by limiting their undulations.

I suggest that realization of the central role of a coherent current of electrons in achieving superconductivity should determine the direction of our search efforts. It is necessary to discover a method of creation of a coherent current of electrons, which does not depend on a low temperature. Creation of such a current should enhance the efficacy of functioning of electrical apparatuses.

It has now been discovered by us quite unexpectedly and unobviously, indeed, a novel method of creation of a coherent electron current, which being maintained, should enhance the efficacy of the electrical devices. Originality of this method is in that it exploits the high speed electrons and it does not depend on the low temperature.

Our invention is based upon our thoroughly elaborated theory of relativity of uncertainty. Detailed description of the theory is given elsewhere (Yabrov, 2009). Here I describe it in an abbreviated form necessary and sufficient for understanding of the method of this patent.

It was discovered by de Broglie that a material particle possesses a dual character of behavior—it behaves both as a wave and as a corpuscle (see de Broglie, 1955). This view of the wave-corpuscular behavior was extended upon all individual objects. The wave function is responsible for the uncertainty of behavior of objects. Hence the universal principle of uncertainty postulated by Heisenberg (see Heisenberg, 1958).

According to the de Broglie's formula, the wave length diminishes with the increase of mass of an object:

$$λ = \frac{ℏ}{mv}$$

λ—wavelength
h—Planc constant
m—mass
v—velocity

As we see, the wave length diminishes with the increase of momentum, which is a product of mass and velocity:

p=mv

p is the momentum

m is the mass

v the velocity

So far, the wave component (wave function) was demonstrated only for the physical particles, but not for the physical bodies. Currently, the failure to detect the wave function of the bodies is being explained by the high mass of the latter (see the equation above—the larger the mass—the shorter the wave. Most physicists accept this explanation: mass of the physical bodies—be it the Sun, or the bowling ball—is so large that their wave function is not detectable—the currently existing technical means do not allow measuring of so short a wave. Thus the conventional view is that any material object—particle or body—does possess a wave function, hence the universality of the principle of uncertainty (see Diner at all., 1984).

In difference from the above conventional view, our theory explains that uncertainty diminishes with the increase of complexity of objects. For example, behavior of atoms in a molecule is uncertain. But the uncertainty of their behavior is limited—otherwise the molecule would not retain its chemical properties. From the chemical point of view—behavior of a molecule is certain. Behavior of the individual atoms and molecules forming a physical body is relatively uncertain, but behavior of this closely related group of particles as a whole, i.e. behavior of a physical body is certain—otherwise the body could not exist as such. Our conclusions are based on facts.

But a question still arises: What happened with the wave? Our theory solves the problem. The answer becomes clear if we add to our quantum mechanical considerations—also those based upon the general theory of relativity. The latter says that a mass—e.g. the Sun, or the Earth, or a grain of sand—is always wrapped up in spacetime. Spacetime is not just an abstract notion—it carries energy. Mass forms a dent in specetime. The shape and completeness of this dent is dictated by the mass. As said Wheeler: “Mass tells spacetime how to curve” (Wheeler, 1990).

It follows from our theory of relativity of uncertainty—that the grip provided by the energy of spacetime thwarts the wave of a body. Wrapped in the spacetime dent, the body looses its wave function—it does not undulate—it behaves with certainty (Yabrov, 2009).

Consider now behavior of an electron. Mass of an electron is so small that it is insufficient for the formation of a spacetime dent. It has both the wave and the corpuscular characteristics. However, as it follows from the de Broglie's formula, the wave diminishes with the increase of momentum. Now we apply the Einstein's principle of equivalence. It says that the genuine mass of an object is identical (equivalent) to mass resulted from acceleration of this object. Based on the principle of equivalence, we conclude that mass of an electron could be enhanced via acceleration of the latter.

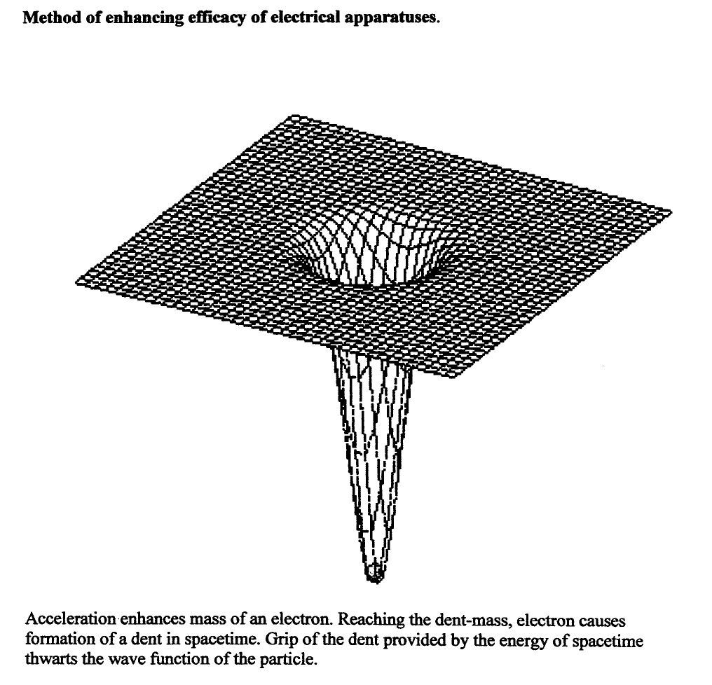

Here is the core of our invention. We should enhance electron's mass to the level sufficient for the formation of the spacetime dent. Then the electron should loose its wave characteristic and will behave with certainty (FIG. 1).

I name the mass, which produces the spacetime dent—the dent-mass. Dent-mass is a new universal constant. Value of the constant of this kind can be obtained only experimentally—via measurement. It cannot be calculated by a pure mathematical method. The precise results of these measurements are not available, yet. But this does not negate the actual existence and importance of the dent-mass constant. It is enough to mention for comparison that the precise value of the gravitational constant still awaits verification, but this does not prevent the Newton's constant being the central constant of physics.

Since the precise value of the dent-mass is not known, we cannot tell precisely the speed at which an electron looses its wave function and starts behaving with certainty. It is important for this invention, however, that we have a new target speed—the dent-mass speed. It should be emphasized that at the considerable speeds, mass increases comparatively more quickly then the speed. The aim of this invention is to enhance mass of the electrons via acceleration so that it reaches the dent-mass. This is an increased speed, which does not necessarily be equal the speed of light.

I acknowledge that this is unusual that the invention operates with the values of mass and speed, which are not precisely determined, yet. But this is the peculiarity of the field of the invention—its practical importance dictates the necessity of a possibly more active implementation. Details of basic research may come later.

The above considerations lead us to the following conclusion. Electrons moving with the dent-mass velocity loose their wave characteristic—they move with certainty—like bullets.

Let us return now to the above description of behavior of the electrons that manifest superconductivity obtained by the existing methods. Under any conditions where phenomenon took place (with any kinds of the superconductors and at any effective temperatures—Tc) electrons move in a coherent current—their wave functions acting in unison. This allows us to speak of a manifestation of a quantum mechanical phenomenon at the macroscopic scale. Low temperature plays a necessary role in the formation of this kind of a current. It assures the coherency of the latter as a result of synchronization of the wave function of individual electrons; and it prevents their deviation by limiting their undulation.

As follows from the description of this invention, we have achieved the formation of a coherent current of electrons moving in unison—based on a different principle and using an absolutely different method. Our current of electrons moving with the dent-mass (or higher) velocity is coherent, indeed—electrons move uniformly—in unison, because of their high speed and because of the absence of their wave characteristic—they do not undulate, do no deviate, and do not scatter. Such a current should enhance the efficacy of functioning of the electrical apparatuses independently of a low temperature.

The following examples are illustrative.

### EXAMPLE 1

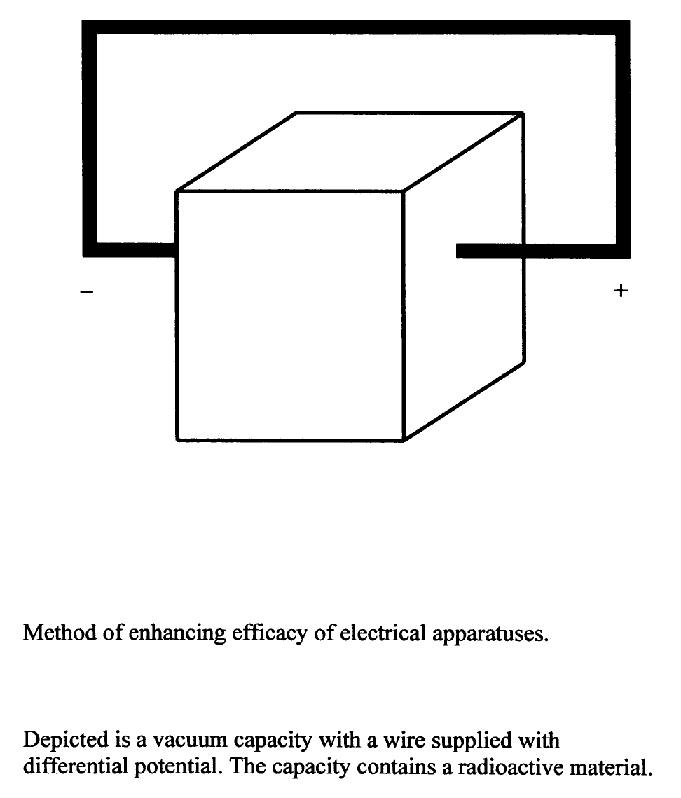

As a model of the high speed electrons, we use beta electrons known to have velocity of 66% to 99% of the speed of light, depending on the medium. Beta electrons are produced in the course of radioactive decay. Our aim is to inject beta electrons into the wire provided with the potential difference and thus create a coherent electrical current of the high speed electrons moving with certainty (FIG. 2).

It should be emphasized that the shape of the container and all the values are selected at will—determined by the conditions of the experiment giving the best results. There are, however, the following certain conditions. The container and the wire handle should be made of a sole piece of material—to avoid junctions, which may create resistance. Four versions of the container depending of the material should be used: three made of different kinds of the superconducting materials, and the fourth—not of a superconducting material conducting electricity. The container and the wire are covered from the outside with an isolating material capable to prevent scatter of the products of decay. Beta electrons emitted by Strontium pass through the cavity of the container and penetrate the walls. The potential difference creates an electrical current of these high speed electrons via the wire.

In order to test, whether superconductivity is achieved, we exploit the capacity of a superconducting current to repel the external magnetic field (Meissner Effect). If superconductivity takes place, a small test-magnet leaned against the wire, or the wall of the container, should not hold.

### EXAMPLE 2

All settings described in Example 1 remain the same. In addition—the container is subjected to low temperature at the level (or below) the critical temperature (Tc) of the superconductive material used. Freezing is applied for the first one to fifteen minutes of action of the potential difference—as a measure initiating superconductivity. Then the established coherent current of the super-speed electrons devoid of their wave function should proceed at room temperature without resistivity; or at least with a higher efficacy than the electrical current obtained by the conventional method.

### EXAMPLE 3

### A Method of Direct Generation of Electricity by a Nuclear Power Plant

Most nuclear power plants generate electricity via conversion of heat produced by splitting atoms. This hit is used for boiling water to produce steam. The steam is used to spin a turbine. The shaft of the turbine spins the generator (a large coil of wire) between two magnets. The spinning coil of wire generates electricity.

Among the products of the fission process are beta-electrons. Emitting of beta electrons by the reactor is demonstrated by the glowing of water cooling the reactor.

Glowing is caused by the beta electrons whose speed exceeds the speed of light in water (Cherenkov Effect).

According to our invention, the beta-electrons emitted continuously by the reactor are collected in a collector and directed into a wire (both made of a superconducting material). Potential difference applied to the body of the collector and the wire form an electrical current immediately (see Examples 1 and 2). This way we should get electricity directly—bypassing the heat, the steam, and the turbine. I foresee two ways of utilization of the beta-electron electricity produced by the nuclear plant. First of all—as such—as a direct source of electricity. Economic considerations should not be the leading ones at this stage of work. It is important to show the possibility of exploitation of beta electrons emitted by the reactor for an immediate generation of electricity. After all, the nuclear plants themselves did not become economically feasible from the initial try. Note: U.S. Pat. No. 4,729,865 mentions generation of an alternating electric current by plasma using a different method (Busch, 1988).

The other consideration is more complex. It can be suggested that the super-speed electrons injected into the current of “normal” electrons produced by the plant might provoke the latter to behave as a superconducting current at room temperature. Again I emphasize that in all these examples the superconductive materials should be used—including the ones connecting the wires with the collecting container. Further studies should show whether we can do without using the superconducting materials having an electrical current of the high speed electrons.

### EXAMPLE 5

A cathode ray tube (CRT) is used as a source of the electrons moving with an augmented speed. An original CRT consists of a vacuum capacity made of durable glass, which encapsulates an electron gun having cathode, which—when heated—emits electrons, and anode provided with the wires to carry the electrical current maintained by the potential difference.

It is known that the electrons move through the vacuum of the CRT with the speed reaching 10% of the speed of light. It is emphasized by the investigators that in the CRT, electrons move in a straight line—“ballisticly”. This speed could be enhanced, e.g., by varying the cathode heating and the potential difference. Our principal modification of the CRT is that we use all the elements related to the electron current—cathode, anode and the wires—all made of the superconductive materials (analogously to the Example 1). Further studies should show whether the larger part of the wire could be replaced by a non-superconducting material. Another necessary condition—all the joints should be made of a special superconductive connecting material to prevent resistivity at the joints.

Thus we have four versions of our CRT-3 made of the different kinds of superconducting materials and the fourth made of a not-superconducting conducting material. If the electrons reach their dent-mass speed, the coherent current of the high speed electrons devoid of their wave function should proceed at room temperature without resistivity; or at least with a higher efficacy then the ordinary electrical current. Note: It should be mentioned that a cathode made of superconductive material has been used to prevent, or minimize the worn out of the emitter (U.S. Pat. No. 5,015,920).

### EXAMPLE 6

All settings described in Example 5 remain the same. In addition—the anode is subjected to low temperature at the level (or below) the critical temperature (Tc) of the superconductive material used. Freezing is applied for the first 1 to 15 minutes of action of the potential difference—as a measure promoting superconductivity. Then the established coherent current of the high speed electrons devoid of their wave function should proceed at room temperature without resistivity; or at least with a higher efficacy then the electrical current obtained by the conventional method.

### EXAMPLE 7

All settings described in Example 5 remain the same. In addition—the anode is subjected to low temperature at the level (or below) the critical temperature (Tc) of the superconductive material used. Freezing is maintained continuously as long as the potential difference is applied. The established coherent current of the high speed electrons devoid of their wave function should proceed at room temperature (as it concerns the entire wire system) without resistivity; or at least with a higher efficacy then the electrical current obtained by the conventional method. In this Example, the Tc temperature is combined with the room temperature continuously. This method is essentially less cumbersome and less expensive than cooling the entire wire system.

The invention covers all the applications where the new principle is used.

1. A coherent current of electrons moving in unison is a key condition for the manifestation of superconductivity by different superconductive materials. The currently used methods exploit low temperatures of various degrees as a necessary technique for the creation of said current of electrons. The invention describes a novel method for the creation of a coherent current of electrons moving in unison, which does not need the conditions of low temperature. The new method uses the high speed electrons whose mass (enhanced by acceleration) is sufficient to cause formation of the space-time dent.
Grip of the spacetime dent thwarts the wave function of electrons. Lacking their wave component electrons do not deviate or scatter. Thus electrons move in unison in a coherent current.

2. Said current of electrons—described in claim 1—enhances efficacy of electrical apparatuses.

3. The current of electrons of claim 1 does not need the condition of low temperatures to provide for superconductivity.

4. Nuclear reactor equipped with a collector for beta electrons supplied with a wire subjected to potential difference. Said collector and wire are made of superconducting materials, or the conventional conducting materials—whichever provides for enhancement of efficacy of the electrical current. This modification allows a direct production of electrical current of beta electrons emitted by the reactor.

5. An electrical apparatus constructed as a cathode ray tube (CRT) with the cathode, anode and the wire made of the superconducting materials.

6. CRT as in claim 7 where anode and the part of wire immediately adjunct to the former are cooled to the corresponding critical temperature—temporarily (1 to 15 min.), or continuously.
